(19) United States
(12) Patent Application Publication
(10) Pub. No.: US 2023/0131315 A1
(43) Pub. Date: Apr. 27, 2023

(54) PROCESS FOR PRODUCTION OF NANO-COATED SUBSTRATE

(71) Applicant: Stora Enso OYJ, Helsinki (FI)

(72) Inventors: Kaj Backfolk, Villmanstrand (FI); Isto Heiskanen, Imatra (FI); Katja Lyytikäinen, Imatra (FI)

(73) Assignee: Stora Enso OYJ, Helsinki (FI)

(21) Appl. No.: 17/996,941

(22) PCT Filed: May 6, 2021
(86) PCT No.: PCT/IB2021/053831

§ 371 Date: Oct. 24, 2022

(30) Foreign Application Priority Data
May 7, 2020 (SE) 2050525-1

(51) Int. Cl. D21H 19/08; D21H 11/16; D21H 25/04; B65D 65/42

(52) U.S. Cl. CPC D21H 19/08; D21H 11/16; D21H 25/04; B65D 65/42

(57) ABSTRACT

The present invention is directed to a process for manufacturing a nano-coated pulp-based substrate comprising the steps of: a) providing a suspension comprising pulp, said pulp having Schopper Riegler value of at least 70°; b) using the suspension of step a) to form a wet web; c) dewatering and/or drying the wet web to form a substrate; d) reducing surface roughness of the substrate; providing a nano-coating on the surface of the substrate obtained in step d) such that a nano-coating having a thickness in the range of from 0.1 nm to 100 nm is provided on the substrate.

### TECHNICAL FIELD

The present invention is directed to a process for manufacturing a nano-coated pulp-based substrate.

### BACKGROUND

Films and barrier papers comprising high amounts of microfibrillated cellulose (MFC) are known in the art. Depending on how they are produced, the films may have particularly advantageous strength and/or barrier properties, whilst being biodegradable and renewable. Films comprising MFC are for example used in the manufacture of packaging materials and may be laminated or otherwise provided on the surface of paper or paperboard materials.

It is known that the barrier properties of MFC films may be negatively influenced by water or moisture. Various chemical and mechanical solutions have been tested such as lamination with thermoplastic polymers.

There is a need for an efficient method for preparing surface treated pulp-based substrates, said surface-treated substrates also providing barrier and strength properties.

Additionally, it would be desirable if such a surface-treated substrate could be compostable and/or easily recyclable and/or repulpable and essentially free from plastic. However, difficulties may arise when providing coatings and surface treatments on cellulose-based substrates. If a dispersion or water based solution is applied onto a thin web or substrate, web breaks or problems with dimensional stability may occur. This is due to water sorption and penetration into the hydrophilic substrate, affecting the hydrogen bonds between the fibrils, fibers, and the additives.

One solution is to increase solids of the applied solutions, although this often leads to higher coat weight and higher viscosity of the solution. High viscosity, on the other hand, generates higher stresses on the substrates and often higher coat weights.

For these reasons, providing sufficient barrier properties is difficult, especially at a low coat weight.

Therefore, aluminum foil or film-forming polymers such as latex or thermoplastic polymers is used for these purposes and generally provides sufficient properties with regard to penetration or diffusion of oil or greases and/or aromas or gas, such as oxygen. The aluminum or film-forming polymers also provide an enhanced water vapor barrier, which is important to barrier and package functionality in high relative humidity conditions or to reduce evaporation of packed liquid products.

However, one issue with the use of aluminum foil is that it poses an environmental challenge, may be a problem in the recycling process and, depending on the amount used, may lead to the packaging material not being compostable. It is therefore desirable to use as small amount of aluminum as possible. However, at the same time it is essential to maintain the barrier properties of the packaging material.

It is known in the art to provide nano-coatings that can be organic or inorganic, such as ceramic or metal nano-coatings. The nano-coatings are very thin, such as from about 0.1 nm to about 100 nm in thickness. For example, metallized surfaces using a very small amount of metal or metal oxides, such as aluminum or TiO₂, Al₂O₃, MgO or ZnO. For example, atomic layer deposition (ALD), dynamic compound deposition (DCD), chemical vapor deposition (CVD), such as plasma CVD, physical vapor deposition (PVD) and metal plasma-deposition are techniques suitable to provide a small amount of metal on a surface. However, it remains essential that the packaging material, when provided with a nano-coating such as being metallized, can maintain barrier properties and is sufficiently crack-resistant.

One issue with film-forming polymers such as latex and thermoplastic fossil-based polymers is that the packaging material obtained is typically not considered as a monomaterial and issues may arise with recycling. A further problem with many film-forming polymers is that the film-forming polymers are usually provided in the form of aqueous solutions or dispersions. The water content of the solutions or dispersions may disrupt the paper substrate. Hydrophilic cellulose materials typically provide barrier properties to oxygen, but are sensitive to water and water vapour.

A further issue when using nano-coatings is that such coatings are sensitive to not only to roughness of the substrate on which it is applied, but also to dust, contaminants and debris that may be present on such surfaces. Such dust, contaminants and debris may cause pinholes in the nano-coating.

Therefore, a substrate adapted such that a very small amount of nano-coating can be applied without deteriorating barrier properties is needed.

### SUMMARY

It has surprisingly been found that some or all of the aforementioned problems can be solved by providing an improved method of manufacturing a nano-coated substrate, having water vapor barrier properties.

It has surprisingly been found that by using a process wherein a suspension comprising pulp is provided, said pulp having Schopper Riegler value of at least 70°, using the suspension to form a wet web, followed by dewatering and/or drying, followed by reducing surface roughness of the substrate, followed by providing a nano-coating such that a nano-coating layer having a thickness in the range of from 0.1 nm to 100 nm is provided on the substrate, advantageous barrier properties, particularly water vapor barrier properties, can be achieved.

Thus, the present invention is directed to a process for the production of a nano-coated substrate comprising the steps of:
a) providing a suspension comprising pulp, said pulp having Schopper Riegler value of at least 70°;
b) using the suspension of step a) to form a wet web;
c) dewatering and/or drying the wet web to form a substrate;
d) reducing surface roughness of the substrate;
e) providing a nano-coating on the surface of the substrate obtained in step d) such that a nano-coating having a thickness in the range of from 0.1 nm to 100 nm is provided on the substrate.

### DETAILED DESCRIPTION

The suspension used in step a) comprises pulp, said pulp having a Schopper Riegler value(SR°) of more than 70 SR°, such as from 70 to 95 SR° or from 75 to 85 SR°. The Schopper-Riegler value can be determined through the standard method defined in EN ISO 5267-1.

The pulp in the suspension can be produced using methods known in the art and may for example be kraft pulp, which has been refined to achieve the desired Schopper Riegler value. The pulp may also comprise microfibrillated cellulose (MFC). The pulp may be a mix of essentially unrefined pulp, mixed with highly refined pulp and/or MFC. The suspension may, in addition to the pulp, comprise additives typically used in papermaking.

The suspension in step a) may comprise a mixture of different types of fibers, such as microfibrillated cellulose, and an amount of other types of fiber, such as kraft fibers, fines, reinforcement fibers, synthetic fibers, dissolving pulp, TMP or CTMP, PGW, etc.

The suspension in step a) may also comprise other process or functional additives, such as fillers, pigments, wet strength chemicals, retention chemicals, cross-linkers, softeners or plasticizers, adhesion primers, wetting agents, biocides, optical dyes, colorants, fluorescent whitening agents, de-foaming chemicals, hydrophobizing chemicals such as AKD, ASA, waxes, resins etc.

The wet web may be formed for example by wet laid or cast forming methods. For wet laid formation, the process may be carried out in a paper making machine such as a fourdrinier or other forming types such as Twin-former or hybrid former. The web can be single or multilayer web or singly or multiply web, made with one or several headboxes.

The microfibrillated cellulose preferably has a Schopper Riegler value (SR°) of more than 70 SR°, or more than 75 SR°, or more than 80 SR°. The microfibrillated cellulose has a surface area of at least 30 m²/g or more preferably more than 60 m²/g or most pref. >90 m²/g when determined according to nitrogen adsorption (BET) method for a solvent exchanged and freeze dried sample.

The microfibrillated cellulose content of the suspension may be in the range of from 15 to 99.9 weight-% based on the weight of solids of the suspension. In one embodiment, the microfibrillated cellulose content of the suspension may be in the range of 30 to 90 weight-%, in the range of 35 to 80 weight-%, or in the range of from 40 to 60 weight-%.

The wet web can be prepared for example by wet laid and cast forming methods. In the wet laid method, the suspension is prepared and provided to a porous wire. The dewatering occurs through the wire fabric and optionally also in a subsequent press section and a drying section. The drying is usually done using convection (cylinder, metal belt) or irradiation drying (IR) or hot air. A typical wet laid is for example the fourdrinier former used in papermaking. In the cast forming method the wet web is formed for example on a polymer or metal belt and the subsequent initial dewatering is predominantly carried out in one direction, such as via evaporation using various known techniques.

The dewatering and/or drying of the web is carried out such that the moisture content at the end of the dewatering and/or drying is preferably less than 50 wt-%, more preferably less than 20 wt-%, most preferably less than 10 wt-%, even more preferably less than 5 wt-%.

The basis weight of the substrate obtained in step c), before being provided with the nano-coating, is preferably less than 100 g/m², more preferably less than 70 g/m² and most preferably less than 35 g/m². The basis weight of the obtained substrate is, before being provided with the nano-coating, preferably at least 10 g/m².

Preferably, the substrate is free from fluorochemicals.

The substrate obtained in step c) may optionally be surface treated by for example calendering prior to step d). Step d) may be carried out in a machine and/or location different from that of step c).

The substrate obtained in step c), i.e. prior to providing the nano-coating on the surface of the substrate, preferably has barrier properties such that the Gurley Hill porosity value of the substrate is higher than 4000 s/100 ml, preferably higher than 6000 s/100 ml and most preferably higher than 10 000 s/100 ml. The Gurley Hill value can be determined using methods known in the art (ISO 5636-5).

The substrate obtained in step c) preferably comprises less than 10 pinholes/m², preferably less than 8 pinholes/m², and more preferably less than 2 pinholes/m², as measured according to standard EN13676:2001.

The step of reducing surface roughness of the substrate involves at least two of the following treatments: corona treatment, flame treatment, plasma treatment and/or dust removal. Dust removal may for example be carried out by using pressurized clean air or gas or using an air-ionizing gun or be electrostatic removal. Preferably the step of reducing surface roughness of the substrate involves at least two of the following treatments: corona treatment, flame treatment and/or plasma treatment. Preferably, at least two separate treatments are applied, wherein the at least two treatments may be the same or different. For example, in one embodiment of the present invention two separate flame treatments are carried out, i.e. a first flame treatment of the substrate is carried out, followed by a second flame treatment. In one embodiment, flame treatment is first carried out, followed by plasma treatment. In other preferred embodiment, electrostatic removal is first carried out, followed by flame treatment. Each treatment is carried out using methods known in the art. The step of reducing surface roughness of the substrate is carried out on one or both sides of the substrate.

The step of reducing the surface roughness of the substrate prepares the substrate for the subsequent nano-coating step and enable the application and use of the very thin nano-coating. More specifically, the step of reducing the surface roughness of the substrate reduces the nano-scale surface roughness.

Nanoscale roughness of a substrate can be determined using methods known in the art. For example, the roughness can be determined by atomic force microscopy or by use of scanning electron microscopy.

The nanoscale surface roughness of the substrate according to the present invention is low, i.e. the surface is very smooth on a nanoscale. Roughness is often described as closely spaced irregularities. Nanoscale roughness can be measured by atomic force microscopy. For example, an area of the substrate obtained in step d) (i.e. before any nano-coating has been applied), preferably an area of between 5 μm×5 μm and 100 μm×100 μm, can be can observed using atomic force microscopy. The surface structure, i.e. peaks and valleys can be determined and the root-mean-square (RMS) roughness or peak-to-valley height parameters can be calculated, quantifying the nanoscale surface roughness (Peltonen J. et al. Langmuir, 2004, 20, 9428-9431). For the substrates obtained in step e) according to the present invention, the RMS determined accordingly is generally below 100 nm, preferably below 80 nm.

The nano-coating is very thin, from 0.1 nm to about 100 nm in thickness. The nano-coating can be organic or inorganic, such as ceramic or metal nano-coatings. For example, metallized surfaces using a very small amount of metal or metal oxides, such as aluminum or TiO₂, Al₂O₃, MgO or ZnO. In one embodiment, the nano-coating comprises aluminum.

The step of providing the nanocoating (step e) of the process) can be carried using for example atomic layer deposition (ALD), dynamic compound deposition (DCD), chemical vapor deposition (CVD), such as plasma CVD, physical vapor deposition (PVD) and metal plasma-deposition. The nano-coating is preferably carried out by atomic layer deposition (ALD). The nano-coating can be an in-line process, i.e. carried out in the same equipment and/or in the same location as steps a) to d). Alternatively, the nano-coating can be carried out separately, i.e. in a separate equipment and/or in another location than steps a) to d). The nano-coating can be carried out on one or both sides of the substrate.

The nano-coating is provided directly on the substrate obtained in step d), i.e. no pre-coating is provided between the substrate obtained in step d) and the nano-coating.

After providing the nano-coating, a protective coating in the form of a binder, varnish or tie layer may optionally be applied on the nano-coating. Examples of binders include microfibrillated cellulose, SB latex, SA latex, PVAc latex, starch, carboxymethylcellulose, polyvinyl alcohol etc. The amount of binder used in a protective coating is typically 1-40 g/m², preferably 1-20 g/m² or 1-10 g/m². Such a protective coating may be provided using methods known in the art. For example, the protective coating can be applied in one or two layers with e.g contact or non-contact deposition techniques. Said protective coating can further provide for example heat sealability, liquid and/or grease resistance, printing surface and rub resistance.

According to a further embodiment of the present invention, there is provided a laminate comprising the nano-coated substrate prepared according to the present invention. Such a laminate may comprise a thermoplastic polymer (fossil based or made from renewable resources) layer, such as any one of a polyethylene, polyvinyl alcohol, EVOH, starch (including modified starches), cellulose derivative (Methyl cellulose, hydroxypropyl cellulose etc), hemicellulose, protein, styrene/butadiene, styrene/acrylate, acryl/vinylacetate, polypropylene, a polyethylene terephthalate, polyethylene furanoate, PVDC, PCL, PHB, PHA, PGA and polylactic acid. The thermoplastic polymer layer can be provided e.g. by extrusion coating, film coating or dispersion coating. This laminate structure may provide for even more superior barrier properties and may be biodegradable and/or compostable and/or repulpable. In one embodiment, the nano-coated substrate according to the present invention can be present between two coating layers, such as between two layers of polyethylene, with or without a tie layer. In one embodiment, the nano-coated substrate according to the present invention can be laminated on a paperboard with or without a protective coating applied on the nano-coating. According to one embodiment of the present invention, the polyethylene may be any one of a high density polyethylene and a low density polyethylene or mixtures or modifications thereof that could readily be selected by a skilled person. According to further embodiment there is provided the nano-coated substrate or the laminate according to the present invention, wherein said nano-coated substrate or said laminate is applied to the surface of any one of a paper product and a board. The nano-coated substrate or laminate can also be part of a flexible packaging material, such as a free standing pouch or bag. The nano-coated substrate or laminate can be incorporated into any type of package, such as a box, bag, a wrapping film, cup, container, tray, bottle etc.

One embodiment of the present invention is a nano-coated substrate produced according to the process of the present invention.

The OTR (oxygen transmission rate) value (measured at standard conditions) of the nano-coated substrate is preferably <5 cc/(m²*day) measured at 50% RH, 23° C., preferably <3, more preferably <2 and most preferably <1 at a grammage of 10-50 g/m².

The water vapor transmission rate of the nano-coated substrate, determined according to the standard ISO 15106-2/ASTM F1249 at 50% relative humidity and 23° C., is less than 5 g/m²/day, more preferably less than 3 g/m²/day.

The thickness of the nano-coated substrate can be selected dependent on the required properties. The thickness may for example be 10-100 μm, such as 20-50 or 30-40 μm, having a grammage of for example 10-100 g/m², such as 20-30 g/m². The nano-coated substrate typically has very good barrier properties (e.g. to gas, fat or grease, aroma, light etc).

A further embodiment of the present invention is a product comprising the nano-coated substrate produced according to the process of the present invention. Typically, the nano-coated substrate according to the present invention is re-pulpable.

One embodiment of the present invention is a flexible package comprising a nano-coated substrate produced according to the process of the present invention. A further embodiment of the invention is a rigid package comprising a nano-coated substrate according to the present invention.

Microfibrillated cellulose (MFC) shall in the context of the patent application mean a nano scale cellulose particle fiber or fibril with at least one dimension less than 100 nm. MFC comprises partly or totally fibrillated cellulose or lignocellulose fibers. The liberated fibrils have a diameter less than 100 nm, whereas the actual fibril diameter or particle size distribution and/or aspect ratio (length/width) depends on the source and the manufacturing methods.

The smallest fibril is called elementary fibril and has a diameter of approximately 2-4 nm (see e.g. Chinga-Carrasco, G., Cellulose fibres, nanofibrils and microfibrils,: The morphological sequence of MFC components from a plant physiology and fibre technology point of view, Nanoscale research letters 2011, 6:417), while it is common that the aggregated form of the elementary fibrils, also defined as microfibril (Fengel, D., Ultrastructural behavior of cell wall polysaccharides, Tappi J., March 1970, Vol 53, No, 3.), is the main product that is obtained when making MFC e.g. by using an extended refining process or pressure-drop disintegration process. Depending on the source and the manufacturing process, the length of the fibrils can vary from around 1 to more than 10 micrometers. A coarse MFC grade might contain a substantial fraction of fibrillated fibers, i.e. protruding fibrils from the tracheid (cellulose fiber), and with a certain amount of fibrils liberated from the tracheid (cellulose fiber).

There are different acronyms for MFC such as cellulose microfibrils, fibrillated cellulose, nanofibrillated cellulose, fibril aggregates, nanoscale cellulose fibrils, cellulose nanofibers, cellulose nanofibrils, cellulose microfibers, cellulose fibrils, microfibrillar cellulose, microfibril aggregrates and cellulose microfibril aggregates. MFC can also be characterized by various physical or physical-chemical properties such as large surface area or its ability to form a gel-like material at low solids (1-5 wt %) when dispersed in water. The cellulose fiber is preferably fibrillated to such an extent that the microfibrillated cellulose has a surface area of at least 30 m²/g or more preferably more than 60 m²/g or most pref. 22 90 m²/g when determined according to nitrogen adsorption (BET) method for a solvent exchanged and freeze dried sample.

Various methods exist to make MFC, such as single or multiple pass refining, pre-hydrolysis followed by refining or high shear disintegration or liberation of fibrils. One or several pre-treatment step is usually required in order to make MFC manufacturing both energy efficient and sustainable. The cellulose fibers of the pulp to be supplied may thus be pre-treated enzymatically or chemically, for example to reduce the quantity of hemicellulose or lignin. The cellulose fibers may be chemically modified before fibrillation, wherein the cellulose molecules contain functional groups other (or more) than found in the original cellulose. Such groups include, among others, carboxymethyl (CM), aldehyde and/or carboxyl groups (cellulose obtained by N-oxyl mediated oxydation, for example “TEMPO”), or quaternary ammonium (cationic cellulose). After being modified or oxidized in one of the above-described methods, it is easier to disintegrate the fibers into MFC or nanofibrillar size fibrils.

The nanofibrillar cellulose may contain some hemicelluloses; the amount is dependent on the plant source. Mechanical disintegration of the pre-treated fibers, e.g. hydrolysed, pre-swelled, or oxidized cellulose raw material is carried out with suitable equipment such as a refiner, grinder, homogenizer, colloider, friction grinder, ultrasound sonicator, fluidizer such as microfluidizer, macrofluidizer or fluidizer-type homogenizer. Depending on the MFC manufacturing method, the product might also contain fines, or nanocrystalline cellulose or e.g. other chemicals present in wood fibers or in papermaking process. The product might also contain various amounts of micron size fiber particles that have not been efficiently fibrillated.

MFC is produced from wood cellulose fibers, both from hardwood or softwood fibers. It can also be made from microbial sources, agricultural fibers such as wheat straw pulp, bamboo, bagasse, or other non-wood fiber sources. It is preferably made from pulp including pulp from virgin fiber, e.g. mechanical, chemical and/or thermomechanical pulps. It can also be made from broke or recycled paper.

In view of the above detailed description of the present invention, other modifications and variations will become apparent to those skilled in the art. However, it should be apparent that such other modifications and variations may be effected without departing from the spirit and scope of the invention.

1. A process for the production of a nano-coated substrate, the process comprising the steps of:
a) providing a suspension comprising pulp, said pulp having Schopper Riegler value of at least 70°;
b) using the suspension of step a) to form a wet web;
c) dewatering, or drying, or dewatering and drying the wet web to form a substrate;
d) reducing a surface roughness of a surface of the substrate;
e) providing a nano-coating on the surface of the substrate obtained in step d) such that a nano-coating having a thickness in a range of from 0.1 nm to 100 nm is provided on the substrate.

2. The process according to claim 1, wherein in step d) at least two treatments are carried out, the at least two treatments selected from a group consisting of: corona treatment, flame treatment, plasma treatment, and dust removal.

3. The process according to claim 2, wherein the at least two treatments comprising two separate flame treatments.

4. The process according to claim 1, wherein the substrate obtained in step c) is calendered prior to step d).

5. The process according to claim 1, wherein the suspension in step a) comprises microfibrillated cellulose.

6. The process according to claim 5, wherein a content of microfibrillated cellulose of the suspension in step a) is at least 60 weight-% based on a weight of solids of the suspension.

7. The process according to claim 1, wherein the nano-coating applied in step e) comprises aluminium.

8. The process according to claim 1, wherein step e) is carried out by atomic layer deposition.

9. A nano-coated substrate obtained according to the process of claim 1.

10. A packaging material comprising; the nano-coated substrate according to claim 9.
